(19) United States
(12) Patent Application Publication
(10) Pub. No.: US 2024/0215416 A1
(43) Pub. Date: Jun. 27, 2024

(54) DISPLAY DEVICE AND METHOD OF MANUFACTURING THE SAME

(71) Applicant: Samsung Display Co., LTD., Yongin-si (KR)

(72) Inventors: GWUI-HYUN PARK, Yongin-si (KR); KOICHI SUGITANI, Yongin-si (KR); HOKYUNG JANG, Yongin-si (KR); SAEHEE HAN, Yongin-si (KR)

(73) Assignee: Samsung Display Co., LTD., Yongin-si (KR)

(21) Appl. No.: 18/390,505

(22) Filed: Dec. 20, 2023

(30) Foreign Application Priority Data
Dec. 21, 2022 (KR) 10-2022-0181014

(51) Int. Cl. H10K 59/80; H10K 71/20

(52) U.S. Cl. CPC H10K 59/8792; H10K 71/233

(57) ABSTRACT

A display device includes a substrate including a light emitting area and a non-light emitting area disposed adjacent to the light emitting area, a light emitting element disposed in the light emitting area on the substrate, a plurality of light blocking patterns disposed above the light emitting element and spaced apart from each other, and a transmission pattern disposed on the light emitting element, surrounding the plurality of light blocking patterns, and including a first organic pattern and a second organic pattern disposed on the first organic pattern.

### CROSS-REFERENCE TO RELATED APPLICATION(S)

This application claims priority to and benefits of Korean Patent Application No. 10-2022-0181014 under 35 USC § 119, filed on Dec. 21, 2022, in the Korean Intellectual Property Office (KIPO), the entire contents of which are incorporated herein by reference.

### BACKGROUND

### 1. Technical Field

Embodiments relate to a display device providing visual information and a method of manufacturing the same.

### 2. Description of the Related Art

As information technology develops, the importance of display devices, which are communication media between users and information, is being highlighted. Accordingly, the use of display devices such as liquid crystal display devices, organic light emitting display devices, plasma display devices, or the like is increasing.

A display device may display an image having a wide viewing angle or, if necessary, the viewing angle of an image displayed on the display device may be limited in order to improve security or image reflection.

### SUMMARY

Embodiments provide a display device with improved display quality.

Embodiments provide a method of manufacturing the display device.

A display device according to an embodiment of the disclosure may include a substrate including a light emitting area and a non-light emitting area disposed adjacent to the light emitting area, a light emitting element disposed in the light emitting area on the substrate, a plurality of light blocking patterns disposed above the light emitting element and spaced apart from each other, and a transmission pattern disposed on the light emitting element, surrounding the plurality of light blocking patterns, and including a first organic pattern and a second organic pattern disposed on the first organic pattern.

In an embodiment, the second organic pattern may include siloxane.

In an embodiment, a thickness of the second organic pattern may be in a range of about 1 μm to about 30 μm.

In an embodiment, the first organic pattern may include an acrylic material.

In an embodiment, a thickness of the first organic pattern may be less than or equal to about 25 μm.

In an embodiment, an etching rate of the second organic pattern may be less than an etching rate of the first organic pattern with respect to oxygen gas.

In an embodiment, an upper surface of each of the plurality of light blocking patterns may be concave in a cross-sectional view.

In an embodiment, each of the plurality of light blocking patterns may include molybdenum-tantalum oxide (MTO) or an organic material including a black pigment.

In an embodiment, each of the plurality of light blocking patterns may not overlap the light emitting area in a plan view, and may overlap the non-light emitting area in a plan view.

In an embodiment, a portion of the plurality of light blocking patterns may overlap the light emitting area in a plan view, and another portion of the plurality of light blocking patterns may overlap the non-light emitting area in a plan view.

In an embodiment, each of the plurality of light blocking patterns may extend in a first direction, and the plurality of light blocking patterns may be spaced apart from each other in a second direction intersecting the first direction.

A method of manufacturing a display device according to an embodiment of the disclosure may include forming a light emitting element on a substrate, forming a first organic layer on the light emitting element, forming a second organic layer on the first organic layer, forming a transmission pattern including a plurality of openings by patterning the first organic layer and the second organic layer, and forming a plurality of light blocking patterns filling the plurality of openings.

In an embodiment, the forming of the transmission pattern may include forming a second organic pattern by etching a portion of the second organic layer, and forming the transmission pattern by forming a first organic pattern by etching a portion of the first organic layer.

In an embodiment, the first organic layer may be etched using the second organic pattern as a mask in the forming of the first organic pattern.

In an embodiment, the forming of the plurality of light blocking patterns may include forming a light blocking layer filling the plurality of openings of the transmission pattern, and forming the plurality of light blocking patterns by etching a portion of an upper part of the light blocking layer.

In an embodiment, the first organic layer may include an acrylic material.

In an embodiment, the second organic layer may include siloxane.

In an embodiment, an etching rate of the second organic layer may be less than an etching rate of the first organic layer with respect to oxygen gas.

In an embodiment, a thickness of the first organic pattern may be less than or equal to about 25 μm.

In an embodiment, a thickness of the second organic pattern may be in a range of about 1 μm to about 30 μm.

In a display device according to embodiments of the disclosure, the display device may include light blocking patterns that control a viewing angle and a transmission pattern surrounding the light blocking patterns. The transmission pattern may include a first and second organic patterns including an organic material having high transmittance. Since the light blocking patterns may be formed using the transmission pattern without a separate hard mask, a side surface of each of the light blocking patterns may have a relatively flat profile in a cross-sectional view. Accordingly, light transmittance and luminance may be improved, and display quality of the display device may be improved.

The first organic pattern may be formed using the second organic pattern as a mask, and the display device may not include a separate light blocking film that controls the viewing angle. Accordingly, an efficiency of a manufacturing process of the display device may be improved.

### BRIEF DESCRIPTION OF THE DRAWINGS

FIG. 1 is a plan view illustrating a display device according to an embodiment of the disclosure.

FIG. 2 is an enlarged plan view of a portion of a display area of the display device of FIG. 1.

FIG. 3 is a schematic cross-sectional view taken along line I-I′ of FIG. 2.

FIG. 4 is a schematic enlarged cross-sectional view of area A of FIG. 3.

FIGS. 5 to 10 are schematic cross-sectional views illustrating a method of manufacturing the display device of FIG. 3.

FIG. 11 is an enlarged plan view of a portion of a display area of a display device according to another embodiment of the disclosure.

FIG. 12 is a schematic cross-sectional view taken along line II-II′ of FIG. 11.

### DETAILED DESCRIPTION OF THE EMBODIMENTS

Hereinafter, display devices in accordance with embodiments will be described in more detail with reference to the accompanying drawings. The same reference numerals are used for the same components in the drawings, and redundant descriptions of the same components will be omitted.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the first direction, the second direction, and the third direction are not limited to three axes of a rectangular coordinate system, such as the x, y, and z axes, and may be interpreted in a broader sense. For example, the first direction, the second direction, and the third direction may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

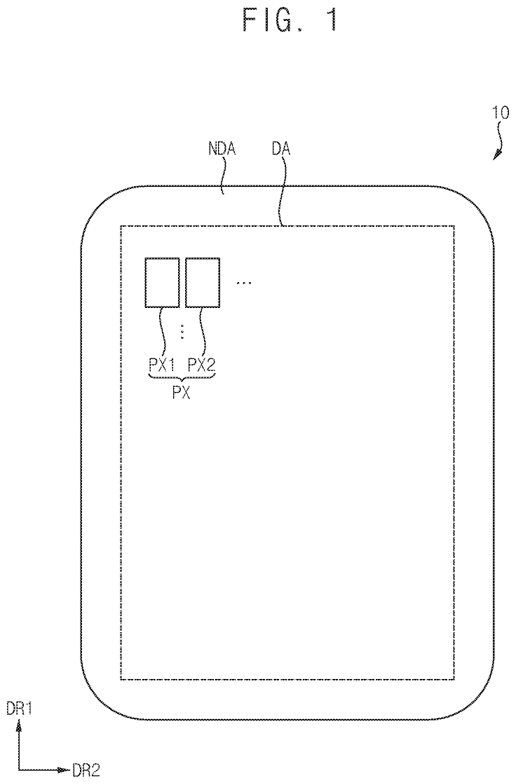

FIG. 1 is a plan view illustrating a display device according to an embodiment of the disclosure.

Referring to FIG. 1, a display device 10 according to an embodiment may include a display area DA and a non-display area NDA.

The display area DA may be an area that displays an image. Multiple pixels PX may be disposed in the display area DA. Each of the pixels PX may emit light. The pixels PX may include a first pixel PX1 and a second pixel PX2. For example, the first pixel PX1 and the second pixel PX2 may simultaneously emit light. In another example, in case that the first pixel PX1 emits light, the second pixel PX2 may not emit light. In another example, in case that the first pixel PX1 does not emit light, the second pixel PX2 may emit light. As each of the pixels PX emits light, the display area DA may display an image.

The pixels PX may be repeatedly arranged in a first direction DR1 and a second direction DR2 intersecting the first direction DR1 in a plan view. For example, the second pixel PX2 may be disposed adjacent to the first pixel PX1. For example, the second pixel PX2 may be disposed adjacent to the first pixel PX1 in the second direction DR2.

The non-display area NDA may be disposed adjacent to the display area DA. For example, the non-display area NDA may surround at least a portion of the display area DA. The non-display area NDA may be an area not displaying an image. A driver may be disposed in the non-display area NDA. The driver may provide signals and/or voltages to the pixels PX. For example, the driver may include a data driver, a gate driver, or the like.

In the disclosure, a plane may be defined by the first direction DR1 and the second direction DR2. For example, the first direction DR1 may be perpendicular to the second direction DR2.

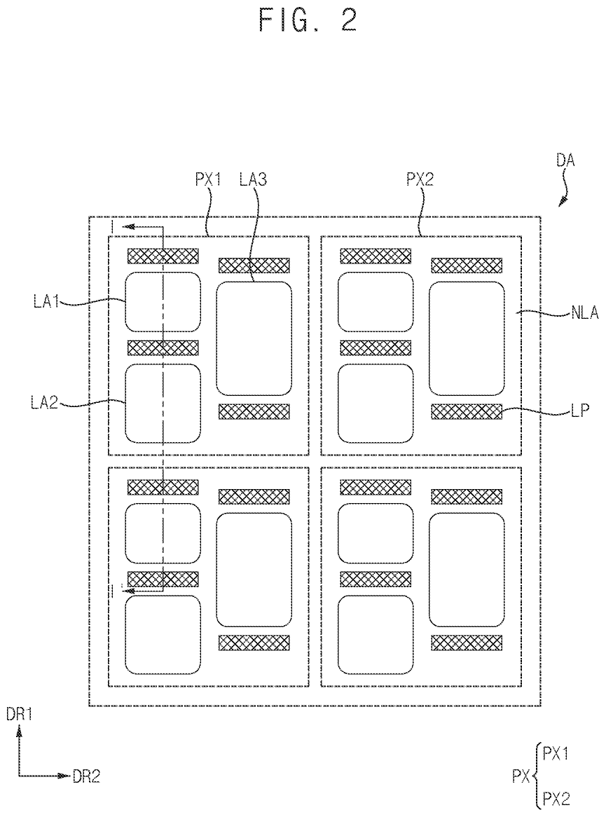

FIG. 2 is an enlarged plan view of a portion of a display area of the display device of FIG. 1.

Referring to FIGS. 1 and 2, the display device 10 may include the display area DA and the non-display area NDA, and the pixels PX may be disposed in the display area DA. The pixels PX may include the first pixel PX1 and the second pixel PX2.

Each of the first pixel PX1 and the second pixel PX2 may include a first light emitting area LA1, a second light emitting area LA2, a third light emitting area LA3, and a non-light emitting area NLA.

Each of the first light emitting area LA1, the second light emitting area LA2, and the third light emitting area LA3 may emit light. In an embodiment, the first light emitting area LA1 may emit light of a first color, the second light emitting area LA2 may emit light of a second color, and the third light emitting area LA3 may emit light of a third color. For example, the first color may be red, the second color may be green, and the third color may be blue. However, the disclosure is not limited thereto. As the light of the first color, the light of the second color, and the light of the third color are combined, each of the first pixel PX1 and the second pixel PX2 may emit light of various colors. The non-light emitting area NLA may not emit light.

The display device 10 may include multiple light blocking patterns LP. In an embodiment, each of the light blocking patterns LP may overlap the non-light emitting area NLA in a plan view. However, each of the light blocking patterns LP may not overlap the first light emitting area LA1, the second light emitting area LA2, and the third light emitting area LA3 in a plan view.

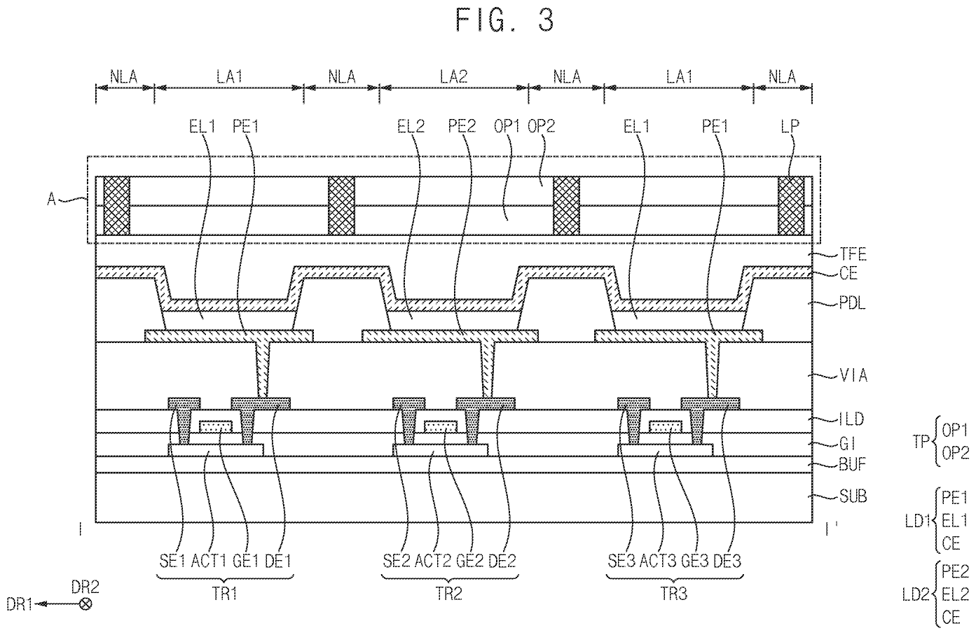

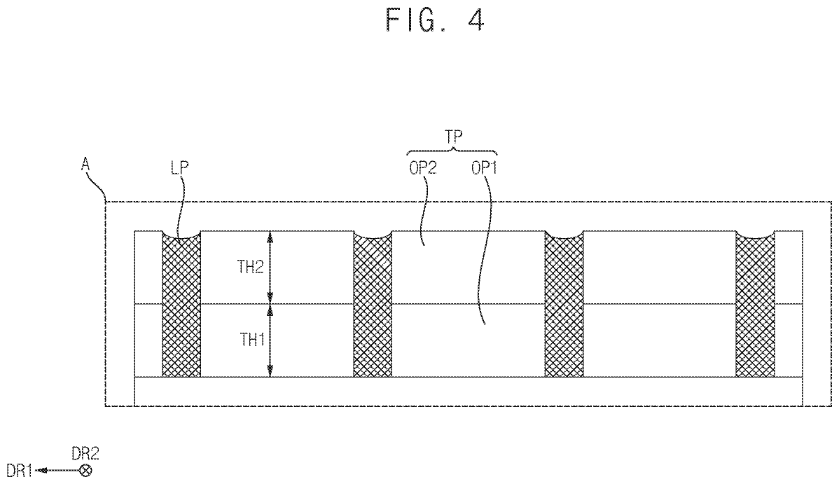

FIG. 3 is a schematic cross-sectional view taken along line I-I′ of FIG. 2. FIG. 4 is a schematic enlarged cross-sectional view of area A of FIG. 3. For example, FIG. 4 may be a schematic enlarged cross-sectional view of the light blocking patterns LP and a transmission pattern TP according to an embodiment.

Referring to FIGS. 2, 3 and 4, the display device 10 may include a substrate SUB, a buffer layer BUF, a first, second, and third transistors TR1, TR2 and TR3, a gate insulating layer GI, an interlayer insulating layer ILD, a via insulating layer VIA, a pixel defining layer PDL, a first and second light emitting elements LD1 and LD2, an encapsulation layer TFE, the light blocking patterns LP, and the transmission pattern TP.

The first transistor TR1 may include a first active pattern ACT1, a first gate electrode GE1, a first source electrode SE1, and a first drain electrode DE1. The second transistor TR2 may include a second active pattern ACT2, a second gate electrode GE2, a second source electrode SE2, and a second drain electrode DE2. The third transistor TR3 may include a third active pattern ACT3, a third gate electrode GE3, a third source electrode SE3, and a third drain electrode DE3.

The first light emitting element LD1 may include a first pixel electrode PE1, a first light emitting layer EL1, and a common electrode CE. The second light emitting element LD2 may include a second pixel electrode PE2, a second light emitting layer EL2, and the common electrode CE.

The substrate SUB may include a transparent material or an opaque material. In an embodiment, the substrate SUB may be a transparent resin substrate. Examples of the transparent resin substrate may include a polyimide substrate or the like. In an embodiment, the substrate SUB may include a first organic layer, a first barrier layer, a second organic layer, or the like. In another embodiment, the substrate SUB may include quartz, synthetic quartz, calcium fluoride, fluorine-doped quartz, a soda lime glass, a non-alkali glass, or the like. These may be used alone or in combination with each other.

The buffer layer BUF may be disposed on the substrate SUB. The buffer layer BUF may prevent diffusion of metal atoms or impurities from the substrate SUB into the first, second, and third transistors TR1, TR2 and TR3. The buffer layer BUF may improve flatness of a surface of the substrate SUB in case that the surface of the substrate SUB is not uniform. The buffer layer BUF may include an inorganic material such as silicon oxide, silicon nitride, silicon oxynitride, or the like. These may be used alone or in combination with each other.

The first, second, and third active patterns ACT1, ACT2, and ACT3 may be disposed on the buffer layer BUF. Each of the first, second, and third active patterns ACT1, ACT2, and ACT3 may include a source area, a drain area, and a channel area disposed between the source area and the drain area. The first, second, and third active patterns ACT1, ACT2, and ACT3 may be formed through a same process, and may include a same material.

Each of the first, second, and third active patterns ACT1, ACT2, and ACT3 may include a silicon semiconductor or an oxide semiconductor. Examples of the silicon semiconductor may include amorphous silicon, polycrystalline silicon, or the like. Examples of the oxide semiconductor may include indium gallium zinc oxide (IGZO), indium tin zinc oxide (ITZO), or the like. These may be used alone or in combination with each other.

The gate insulating layer GI may be disposed on the buffer layer BUF. The gate insulating layer GI may sufficiently cover the first, second, and third active patterns ACT1, ACT2, and ACT3, and may have a substantially flat upper surface without a step on the first, second, and third active patterns ACT1, ACT2, and ACT3. In another embodiment, the gate insulating layer GI may cover the first, second, and third active patterns ACT1, ACT2, and ACT3, and may be disposed along a profile of each of the first, second, and third active patterns ACT1, ACT2, and ACT3 with a uniform thickness. The gate insulating layer GI may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), or the like. These may be used alone or in combination with each other.

The first, second, and third gate electrodes GE1, GE2, and GE3 may be disposed on the gate insulating layer GI. The first gate electrode GE1 may overlap the channel area of the first active pattern ACT1, the second gate electrode GE2 may overlap the channel area of the second active pattern ACT2, and the third gate electrode GE3 may overlap the channel area of the third active pattern ACT3 in a plan view. The first, second, and third gate electrodes GE1, GE2, and GE3 may be formed through a same process, and may include a same material.

Each of the first, second, and third gate electrodes GE1, GE2, and GE3 may include a metal, a conductive metal oxide, a metal nitride, or the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), or the like. Examples of the conductive metal oxide may include indium tin oxide, indium zinc oxide, or the like. Examples of the metal nitride may include aluminum nitride (AlNₓ), tungsten nitride (WNₓ), chromium nitride (CrNₓ), or the like. These may be used alone or in combination with each other.

The interlayer insulating layer ILD may be disposed on the gate insulating layer GI. The interlayer insulating layer ILD may sufficiently cover the first, second, and third gate electrodes GE1, GE2, and GE3, and may have a substantially flat upper surface without a step on the first, second, and third gate electrodes GE1, GE2, and GE3. In another embodiment, the interlayer insulating layer ILD may cover the first, second, and third gate electrodes GE1, GE2, and GE3, and may be disposed along a profile of each of the first, second, and third gate electrodes GE1, GE2, and GE3 with a uniform thickness. The interlayer insulating layer ILD may include an inorganic material such as silicon oxide, silicon nitride, silicon carbide, silicon oxynitride, silicon oxycarbide, or the like. These may be used alone or in combination with each other.

The first, second, and third source electrodes SE1, SE2, and SE3 may be disposed on the interlayer insulating layer ILD. The first source electrode SE1 may be connected to the source area of the first active pattern ACT1 through a contact hole penetrating the gate insulating layer GI and the interlayer insulating layer ILD. The second source electrode SE2 may be connected to the source area of the second active pattern ACT2 through a contact hole penetrating the gate insulating layer GI and the interlayer insulating layer ILD. The third source electrode SE3 may be connected to the source area of the third active pattern ACT3 through a contact hole penetrating the gate insulating layer GI and the interlayer insulating layer ILD.

The first, second, and third drain electrodes DE1, DE2, and DE3 may be disposed on the interlayer insulating layer ILD. The first drain electrode DE1 may be connected to the drain area of the first active pattern ACT1 through a contact hole penetrating the gate insulating layer GI and the interlayer insulating layer ILD. The second drain electrode DE2 may be connected to the drain area of the second active pattern ACT2 through a contact hole penetrating the gate insulating layer GI and the interlayer insulating layer ILD. The third drain electrode DE3 may be connected to the drain area of the third active pattern ACT3 through a contact hole penetrating the gate insulating layer GI and the interlayer insulating layer ILD.

The first, second, and third source electrodes SE1, SE2, and SE3 and the first, second, and third drain electrodes DE1, DE2, and DE3 may be formed through a same process, and may include a same material. Each of the first, second, and third source electrodes SE1, SE2, and SE3 and the first, second, and third drain electrodes DE1, DE2, and DE3 may include a metal, an alloy, a metal nitride, a conductive metal oxide, a transparent conductive material, or the like. These may be used alone or in combination with each other.

Accordingly, the first transistor TR1 including the first active pattern ACT1, the first gate electrode GE1, the first source electrode SE1, and the first drain electrode DE1 may be disposed on the substrate SUB. The second transistor TR2 including the second active pattern ACT2, the second gate electrode GE2, the second source electrode SE2, and the second drain electrode DE2 may be disposed on the substrate SUB. The third transistor TR3 including the third active pattern ACT3, the third gate electrode GE3, the third source electrode SE3, and the third drain electrode DE3 may be disposed on the substrate SUB.

The via insulating layer VIA may be disposed on the interlayer insulating layer ILD. The via insulating layer VIA may sufficiently cover the first, second, and third source electrodes SE1, SE2, and SE3 and the first, second, and third drain electrodes DE1, DE2, and DE. The via insulating layer VIA may include an organic material such as a phenolic resin, a polyacrylates resin, a polyimide resin, a polyamide resin, a siloxane resin, an epoxy resin, or the like. These may be used alone or in combination with each other.

The first and second pixel electrodes PE1 and PE2 may be disposed on the via insulating layer VIA. Each of the first pixel electrodes PE1 may overlap the first light emitting area LA1 in a plan view, and the second pixel electrode PE2 may overlap the second light emitting area LA2 in a plan view. The first pixel electrodes PE1 may be connected to each of the first and third drain electrodes DE1 and DE3 through a contact hole penetrating the via insulating layer VIA. The second pixel electrode PE2 may be connected to the second drain electrode DE2 through a contact hole penetrating the via insulating layer VIA.

The first and second pixel electrodes PE1 and PE2 may be formed through a same process, and may include a same material. Each of the first and second pixel electrodes PE1 and PE2 may include a metal, an alloy, a metal nitride, a conductive metal oxide, a transparent conductive material, or the like. These may be used alone or in combination with each other. For example, each of the first and second pixel electrodes PE1 and PE2 may operate as an anode.

The pixel defining layer PDL may be disposed on the via insulating layer VIA. The pixel defining layer PDL may overlap the non-light emitting area NLA in a plan view. The pixel defining layer PDL may cover both sides of each of the first and second pixel electrodes PE1 and PE2. An opening exposing a portion of an upper surface of each of the first and second pixel electrodes PE1 and PE2 may be defined in the pixel defining layer PDL. The pixel defining layer PDL may include an organic material or an inorganic material. For example, the pixel defining layer PDL may include an organic material such as an epoxy resin, a siloxane resin, or the like. These may be used alone or in combination with each other. In another example, the pixel defining layer PDL may further include a light blocking material including a black pigment, a black dye, or the like.

The first light emitting layer EL1 may be disposed on the first pixel electrode PE1, and the second light emitting layer EL2 may be disposed on the second pixel electrode PE2. Each of the first and second light emitting layers EL1 and EL2 may include an organic material that emits light of a color (a predetermined or a selectable color). For example, the first light emitting layer EL1 may include an organic material that emits red light, and the second light emitting layer EL2 may include an organic material that emits green light. However, the disclosure is not limited thereto.

The common electrode CE may be disposed on the first light emitting layer EL1, the second light emitting layer EL2, and the pixel defining layer PDL. The common electrode CE may be a plate electrode. The common electrode CE may include a metal, an alloy, a metal nitride, a conductive metal oxide, a transparent conductive material, or the like. These may be used alone or in combination with each other. For example, the common electrode CE may operate as a cathode.

Accordingly, the first light emitting element LD1 including the first pixel electrode PE1, the first light emitting layer EL1, and the common electrode CE may be disposed in the first light emitting area LA1 on the substrate SUB. The second light emitting element LD2 including the second pixel electrode PE2, the second light emitting layer EL2, and the common electrode CE may be disposed in the second light emitting area LA2 on the substrate SUB.

The encapsulation layer TFE may be disposed on the common electrode CE. The encapsulation layer TFE may prevent impurities, moisture, air, or the like from permeating the first and second light emitting elements LD1 and LD2 from an outside. In an embodiment, the encapsulation layer TFE may include at least one inorganic layer and at least one organic layer. For example, the organic layer and the inorganic layer may be alternately stacked each other. In another embodiment, the encapsulation layer TFE may be provided as an encapsulation substrate.

The light blocking patterns LP may be disposed on the encapsulation layer TFE. The light blocking patterns LP may be spaced apart from each other in a direction. Each of the light blocking patterns LP may overlap the non-light emitting area NLA in a plan view. In an embodiment, an upper surface of each of the light blocking patterns LP may have a concave shape in a cross-sectional view.

Light emitted from the first and second light emitting elements LD1 and LD2 may be incident on the light blocking patterns LP, or may pass between the light blocking patterns LP. The light incident on the light blocking patterns LP may be reflected from the light blocking patterns LP, may be transmitted through the light blocking patterns LP, or may be absorbed by the light blocking patterns LP. In an embodiment, most of the light incident on the light blocking patterns LP may be absorbed by the light blocking patterns LP. Accordingly, the light blocking patterns LP may control a viewing angle of the display device 10.

In an embodiment, each of the light blocking patterns LP may include molybdenum-tantalum oxide (MTO). For example, each of the light blocking patterns LP may have a single layer structure including MTO. In another example, each of the light blocking patterns LP may have a multilayer structure. Each of the light blocking patterns LP may have a double layer structure including MTO/Mo, MTO/Cu, MTO/Al, or the like. In another example, each of the light blocking patterns LP may have a triple layer structure including MTO/Mo/MTO, MTO/Cu/MTO, MTO/Al/MTO, or the like. These may be used alone or in combination with each other.

In another embodiment, each of the light blocking patterns LP may include an organic material including a black pigment.

However, each of the light blocking patterns LP is not limited thereto. For example, the light blocking patterns LP may include various materials having relatively low transmittance and reflectance and relatively high absorbance.

The transmission pattern TP may be disposed on the encapsulation layer TFE. The transmission pattern TP may surround the light blocking patterns LP. Light emitted from the first and second light emitting elements LD1 and LD2 may pass through the transmission pattern TP.

The transmission pattern TP may have a substantially flat upper surface. For example, the upper surface of the transmission pattern TP and the upper surface of the light blocking patterns LP disposed on both sides of the transmission pattern TP may be positioned at a same level. In another example, the upper surface of the transmission pattern TP may be higher than the upper surface of the light blocking patterns LP.

In an embodiment, the transmission pattern TP may include a first organic pattern OP1 and a second organic pattern OP2 disposed on the first organic pattern OP1. The first organic pattern OP1 and the second organic pattern OP2 may overlap each other in a plan view.

In an embodiment, each of the first organic pattern OP1 and the second organic pattern OP2 may include a transparent organic material. Each of the first organic pattern OP1 and the second organic pattern OP2 may include an organic material having high transmittance.

The first organic pattern OP1 and the second organic pattern OP2 may include different materials. An etching rate of the second organic pattern OP2 may be lower than an etching rate of the first organic pattern OP1 with respect to oxygen gas (O₂ gas). For example, the first organic pattern OP1 may include an acrylic material, and the second organic pattern OP2 may include siloxane.

In an embodiment, a thickness TH1 of the first organic pattern OP1 may be less than or equal to about 25 μm in a thickness direction of the substrate SUB. A thickness TH2 of the second organic pattern OP2 may be in a range of about 1 μm to about 30 μm in a thickness direction of the substrate SUB. However, the disclosure is not limited thereto.

The display device 10 according to an embodiment of the disclosure may include the light blocking patterns LP that controls the viewing angle and the transmission pattern TP surrounding the light blocking patterns LP in a plan view. The transmission pattern TP may include the first and second organic patterns OP1 and OP2 including an organic material having high transmittance. Since the light blocking patterns LP may be formed using the transmission pattern TP without a separate hard mask, a side surface of each of the light blocking patterns LP may have a relatively flat profile in a cross-sectional view. Accordingly, light transmittance and luminance may be improved, and display quality of the display device 10 may be improved.

The first organic pattern OP1 may be formed using the second organic pattern OP2 as a mask, and the display device 10 may not need a separate light blocking film. Accordingly, an efficiency of a manufacturing process of the display device 10 may be improved.

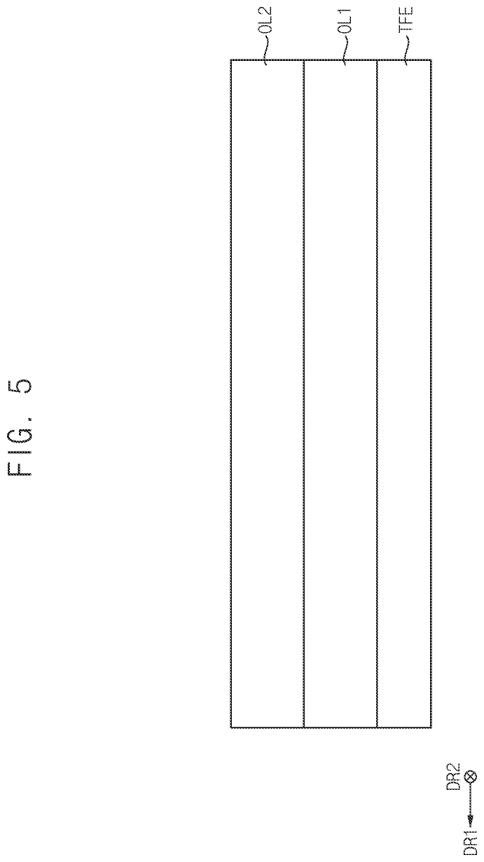

FIGS. 5 to 10 are schematic cross-sectional views illustrating a method of manufacturing the display device of FIG. 3. For example, FIGS. 5 to 10 may be schematic cross-sectional views illustrating a method of manufacturing the light blocking patterns LP and the transmission pattern TP included in the display device 10 of FIG. 3 according to an embodiment.

Referring to FIGS. 3 and 5, the buffer layer BUF, the first, second, and third active patterns ACT1, ACT2, and ACT3, the gate insulating layer GI, the first, second, and third gate electrodes GE1, GE2, and GE3, the interlayer insulating layer ILD, the first, second, and third source electrodes SE1, SE2, and SE3, the first, second, and third drain electrodes DE1, DE2, and DE3, the via insulating layer VIA, the first and second pixel electrodes PE1 and PE2, the pixel defining layer PDL, the first and second light emitting layers EL1 and EL2, the common electrode CE, and the encapsulation layer TFE may be sequentially formed on the substrate SUB.

A first organic layer OL1 and a second organic layer OL2 may be sequentially formed on the encapsulation layer TFE. In an embodiment, each of the first organic layer OL1 and the second organic layer OL2 may include a transparent organic material. The first organic layer OL1 and the second organic layer OL2 may include different materials. An etching rate of the second organic layer OL2 may be lower than an etching rate of the first organic layer OL1 with respect to oxygen gas. For example, the first organic layer OL1 may include an acrylic material, and the second organic layer OL2 may include siloxane.

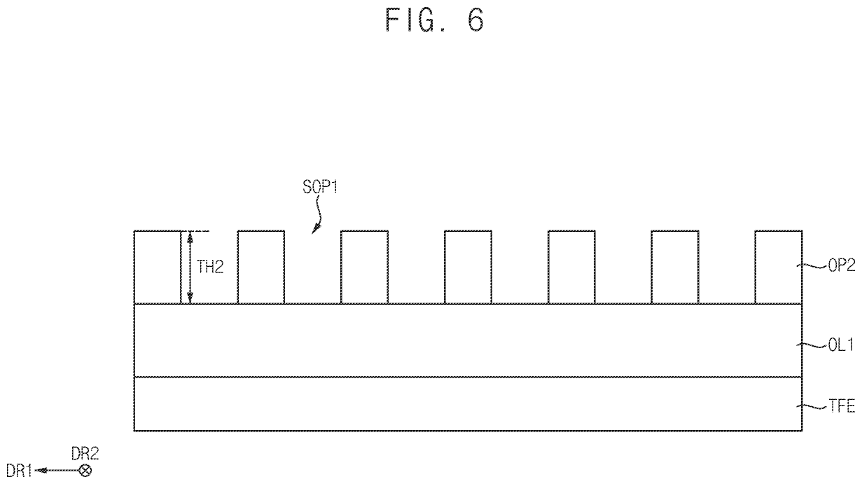

Referring to FIGS. 5 and 6, a portion of the second organic layer OL2 may be etched to form the second organic pattern OP2.

In an embodiment, multiple first sub-openings SOP1 may be formed by dry etching the portion of the second organic layer OL2 through a photolithography process. Accordingly, the second organic pattern OP2 including the first sub-openings SOP1 may be formed. In an embodiment, the thickness TH2 of the second organic pattern OP2 may be in a range of about 1 μm to about 30 μm in a thickness direction of the substrate SUB. However, the disclosure is not limited thereto.

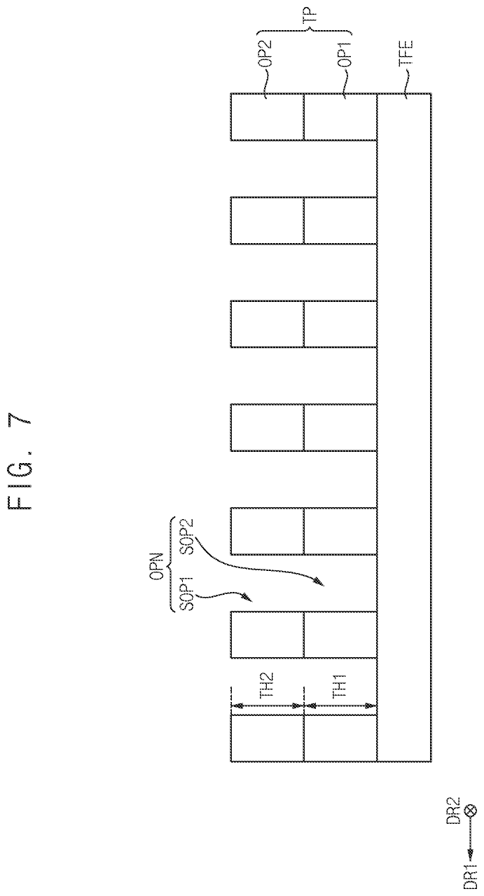

Referring to FIGS. 6 and 7, a portion of the first organic layer OL1 may be etched to form the first organic pattern OP1.

In an embodiment, multiple second sub-openings SOP2 may be formed by dry etching the portion of the first organic layer OL1 using the second organic pattern OP2 as a mask. The portion of the first organic layer OL1 may be dry etched by oxygen gas. Since the etching rate of the second organic layer OL2 is lower than the etching rate of the first organic layer OL1 with respect to oxygen gas, the second organic pattern OP2 may hardly be etched. Accordingly, the first organic pattern OP1 including the second sub-openings SOP2 may be formed. In an embodiment, the thickness TH1 of the first organic pattern OP1 may be less than or equal to about 25 μm in a thickness direction of the substrate SUB. However, the disclosure is not limited thereto.

The transmission pattern TP may be formed by forming the first organic pattern OP1 and the second organic pattern OP2. The first sub-openings SOP1 and the second sub-openings SOP2 may define multiple openings OPN. For example, the transmission pattern TP including the openings OPN may be formed.

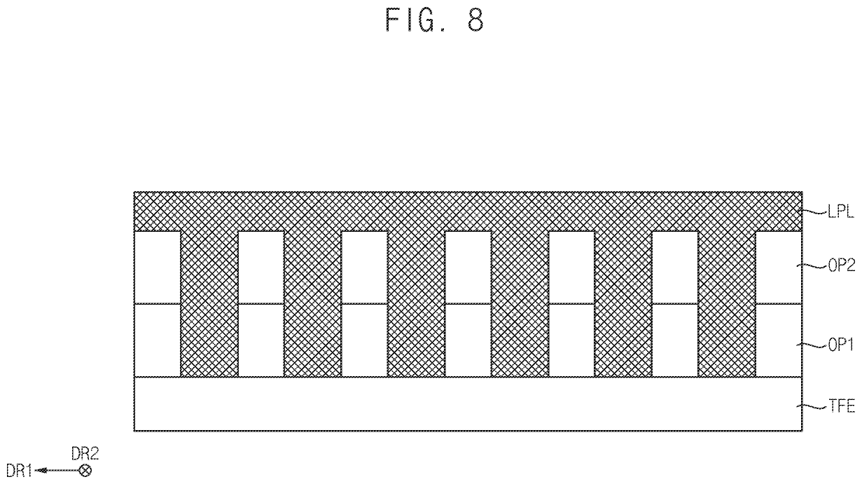

Referring to FIGS. 7 and 8, a light blocking layer LPL may be formed on the encapsulation layer TFE. For example, the light blocking layer LPL may include MTO or an organic material including a black pigment.

The light blocking layer LPL may be formed to fill the openings OPN defined in the transmission pattern TP. The light blocking layer LPL may be formed to sufficiently cover the upper surface of the transmission pattern TP. For example, an upper surface of the light blocking layer LPL may be higher than the upper surface of the transmission pattern TP.

Referring to FIGS. 8, 9 and 10, a portion of the light blocking layer LPL may be etched to form the light blocking patterns LP.

In an embodiment, the light blocking patterns LP filling the openings OPN may be formed by dry etching the portion of an upper part of the light blocking layer LPL.

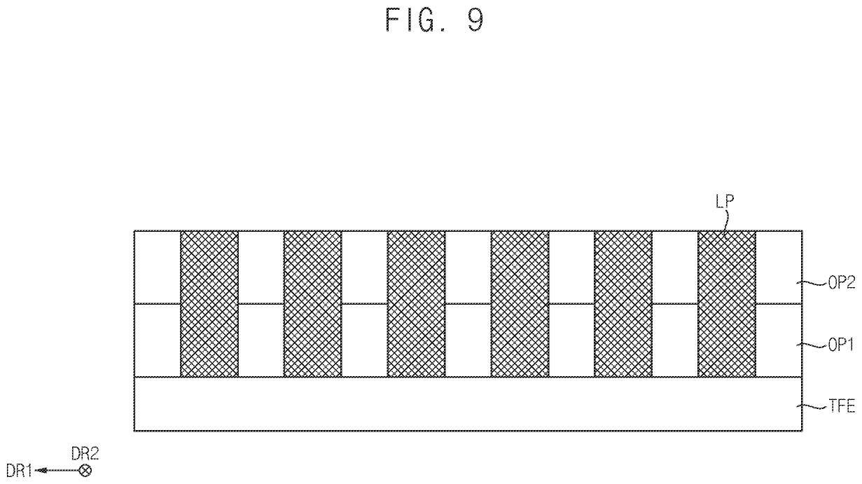

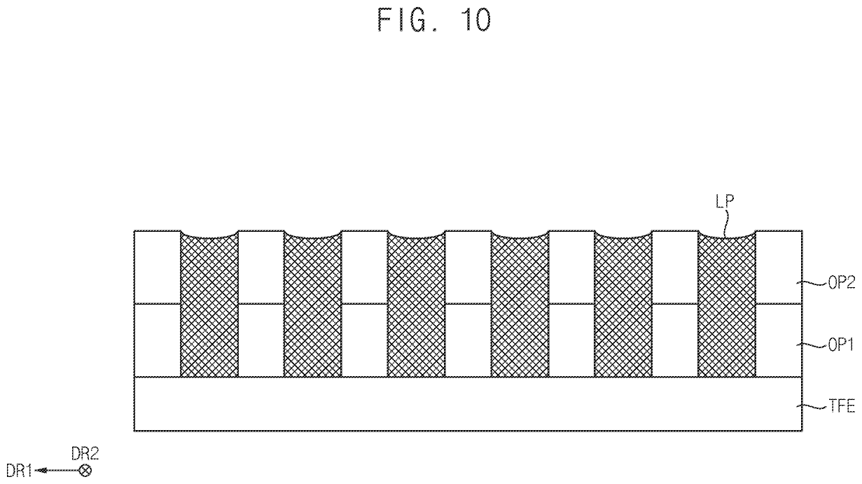

For example, the upper surface of each of the light blocking patterns LP may be flat in a cross-sectional view (see FIG. 9). In another example, the upper surface of each of the light blocking patterns LP may be concave in a cross-sectional view (see FIG. 10).

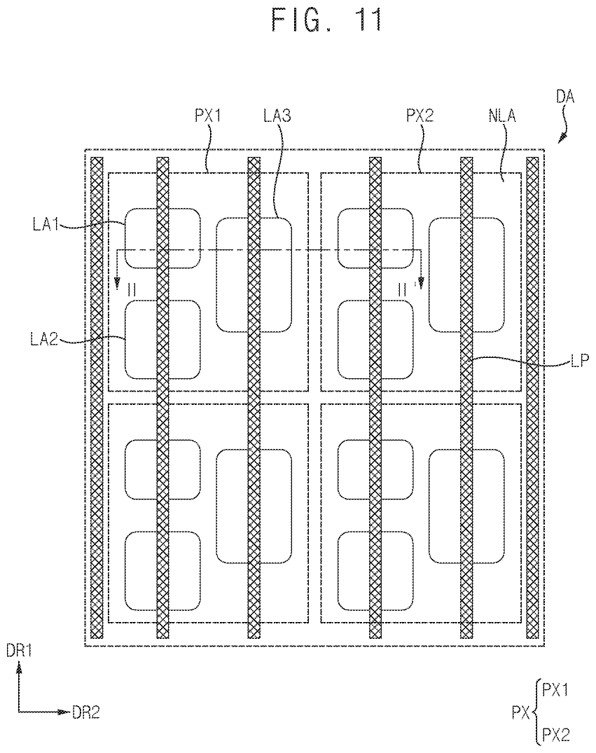

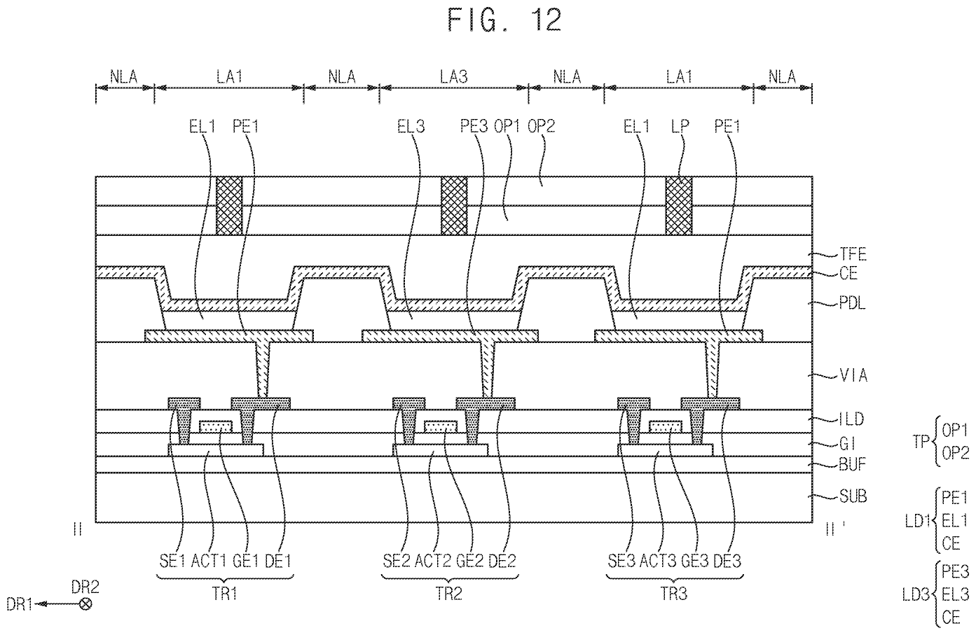

FIG. 11 is an enlarged plan view of a portion of a display area of a display device according to another embodiment of the disclosure. FIG. 12 is a schematic cross-sectional view taken along line II-II′ of FIG. 11.

Referring to FIGS. 11 and 12, a display device according to another embodiment of the disclosure may include a substrate SUB, a buffer layer BUF, first, second, and third transistors TR1, TR2, and TR3, a gate insulating layer GI, an interlayer insulating layer ILD, a via insulating layer VIA, a pixel defining layer PDL, first and third light emitting elements LD1 and LD3, an encapsulation layer TFE, multiple light blocking patterns LP, and a transmission pattern TP.

Hereinafter, descriptions overlapping those of the display device 10 described with reference to FIGS. 1, 2, 3 and 4 will be omitted or simplified.

The light blocking patterns LP may be disposed on the encapsulation layer TFE. In an embodiment, the light blocking patterns LP may be arranged in a direction and spaced apart from each other in the direction. Each of the light blocking patterns LP may extend in the first direction DR1. The light blocking patterns LP may be spaced apart from each other in the second direction DR2 intersecting the first direction DR1. The light blocking patterns LP may be arranged parallel to each other.

A portion of the light blocking patterns LP may overlap the first, second, and third light emitting areas LA1, LA2, and LA3 in a plan view. For example, the portion of the light blocking patterns LP may overlap the first and third light emitting elements LD1 and LD3 in a plan view. Another portion of the light blocking patterns LP may overlap the non-light emitting area NLA in a plan view.

The disclosure can be applied to various display devices. For example, the disclosure may be applicable to various display devices such as display devices for vehicles, ships, aircraft, portable communication devices, display devices for exhibition or information transmission, medical display devices, and the like.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a substrate including a light emitting area and a non-light emitting area disposed adjacent to the light emitting area;
a light emitting element disposed in the light emitting area on the substrate;
a plurality of light blocking patterns disposed above the light emitting element and spaced apart from each other; and
a transmission pattern disposed on the light emitting element, surrounding the plurality of light blocking patterns, and including a first organic pattern and a second organic pattern disposed on the first organic pattern.

2. The display device of claim 1, wherein the second organic pattern includes siloxane.

3. The display device of claim 2, wherein a thickness of the second organic pattern is in a range of about 1 μm to about 30 μm.

4. The display device of claim 1, wherein the first organic pattern includes an acrylic material.

5. The display device of claim 4, wherein a thickness of the first organic pattern is less than or equal to about 25 μm.

6. The display device of claim 1, wherein an etching rate of the second organic pattern is less than an etching rate of the first organic pattern with respect to oxygen gas.

7. The display device of claim 1, wherein an upper surface of each of the plurality of light blocking patterns is concave in a cross-sectional view.

8. The display device of claim 1, wherein each of the plurality of light blocking patterns includes molybdenum-tantalum oxide (MTO) or an organic material including a black pigment.

9. The display device of claim 1, wherein each of the plurality of light blocking patterns does not overlap the light emitting area in a plan view, and overlaps the non-light emitting area in a plan view.

10. The display device of claim 1, wherein
a portion of the plurality of light blocking patterns overlaps the light emitting area in a plan view, and
another portion of the plurality of light blocking patterns overlaps the non-light emitting area in a plan view.

11. The display device of claim 10, wherein
each of the plurality of light blocking patterns extends in a first direction, and
the plurality of light blocking patterns are spaced apart from each other in a second direction intersecting the first direction.

12. A method of manufacturing a display device, the method comprising:
forming a light emitting element on a substrate;
forming a first organic layer on the light emitting element;
forming a second organic layer on the first organic layer;
forming a transmission pattern including a plurality of openings by patterning the first organic layer and the second organic layer; and
forming a plurality of light blocking patterns filling the plurality of openings.

13. The method of claim 12, wherein the forming of the transmission pattern includes:
forming a second organic pattern by etching a portion of the second organic layer; and
forming the transmission pattern by forming a first organic pattern by etching a portion of the first organic layer.

14. The method of claim 13, wherein the first organic layer is etched using the second organic pattern as a mask in the forming of the first organic pattern.

15. The method of claim 12, wherein the forming of the plurality of light blocking patterns includes:
forming a light blocking layer filling the plurality of openings of the transmission pattern; and
forming the plurality of light blocking patterns by etching a portion of an upper part of the light blocking layer.

16. The method of claim 12, wherein the first organic layer includes an acrylic material.

17. The method of claim 12, wherein the second organic layer includes siloxane.

18. The method of claim 12, wherein an etching rate of the second organic layer is less than an etching rate of the first organic layer with respect to oxygen gas.

19. The method of claim 13, wherein a thickness of the first organic pattern is less than or equal to about 25 μm.

20. The method of claim 13, wherein a thickness of the second organic pattern is in a range of about 1 μm to about 30 μm.
